(19) United States
(12) Patent Application Publication
(10) Pub. No.: US 2007/0077739 A1
(43) Pub. Date: Apr. 5, 2007

(54) Carbon controlled fixed charge process

(76) Inventors: Cory E. Weber, Hillsboro, OR (US); Keith E. Zawadzki, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/240,841

(22) Filed: Sep. 30, 2005

(51) Int. Cl. H01L 21/425; H01L 21/336; H01L 29/76; H01L 29/94; H01L 31/00

(52) U.S. Cl. 438/528; 438/303; 257/408

(57) ABSTRACT

Carbon may be implanted into a p-type silicon channel to form a carbon region in an n-type metal oxide semiconductor (NMOS) transistor. After an annealing process, the implanted carbon may diffuse from the channel into an interface of a gate dielectric layer and the channel. The diffusion may cause an increase in fixed charge at the silicon surface. Thus, the threshold voltage of the NMOS transistor may be reduced.

### BACKGROUND

1. Field

Fabrication of integrated circuits.

2. Background

Integrated circuits based on metal-gate technology have received renewed interest for high performance, low-power applications. Gate electrodes made of metal instead of polysilicon tend to provide higher channel capacitance. Channel capacitance relates to the amount of charge in the metal-oxide semiconductor field-effect transistor (MOSFET) channel for a given gate voltage. Higher channel capacitance means more channel charge and more drive current for a MOSFET. In the following descriptions, the MOSFET will be referred to as the MOS transistor or the MOS.

Work function is the amount of energy required for electrons to escape the surface of a material. In a MOS transistor, work function of the gate is closely related to the type of gate material and the threshold voltage of the transistor. The threshold voltage is the voltage required for turning on a transistor. The threshold voltage of a transistor is preferably to be low to improve the performance. The same metal gate tends to have different influence on the threshold voltages of an n-type MOS (NMOS) and a p-type MOS (PMOS). Thus, to optimize the performance of a complementary MOS (CMOS) transistor that includes both PMOS and NMOS, a relatively complex process is often used that involves the deposition of two different metal gates, one for PMOS and the other for NMOS. If the same metal gates are used for both NMOS and PMOS transistors, the doping in the NMOS channel may be reduced to improve the threshold voltage of the NMOS. However, the reduction in channel doping worsens a phenomenon generally known as the short channel effect, requiring the use of a longer channel and thus degrading performance.

### BRIEF DESCRIPTION OF THE DRAWINGS

Embodiments are illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

FIG. 1 shows a cross-sectional view of a semiconductor structure including a p-type metal oxide semiconductor (PMOS) transistor and a carbon-implanted n-type metal oxide semiconductor (NMOS) transistor;

FIG. 2 shows a carbon region between a channel and a gate dielectric layer of the NMOS;

FIG. 3 is a flowchart showing the process of the semiconductor structure of FIG. 1;

FIG. 4 is a diagram of experimental data showing long channel threshold voltage versus carbon dose in the well regions of the NMOS and the PMOS;

FIG. 5 shows experimental data and simulations of NMOS long channel mobility versus threshold voltage for carbon dose in the well region of the NMOS; and

FIG. 6 shows a cross-sectional view of an integrated circuit package comprising the semiconductor structure of FIG. 1.

### DETAILED DESCRIPTION

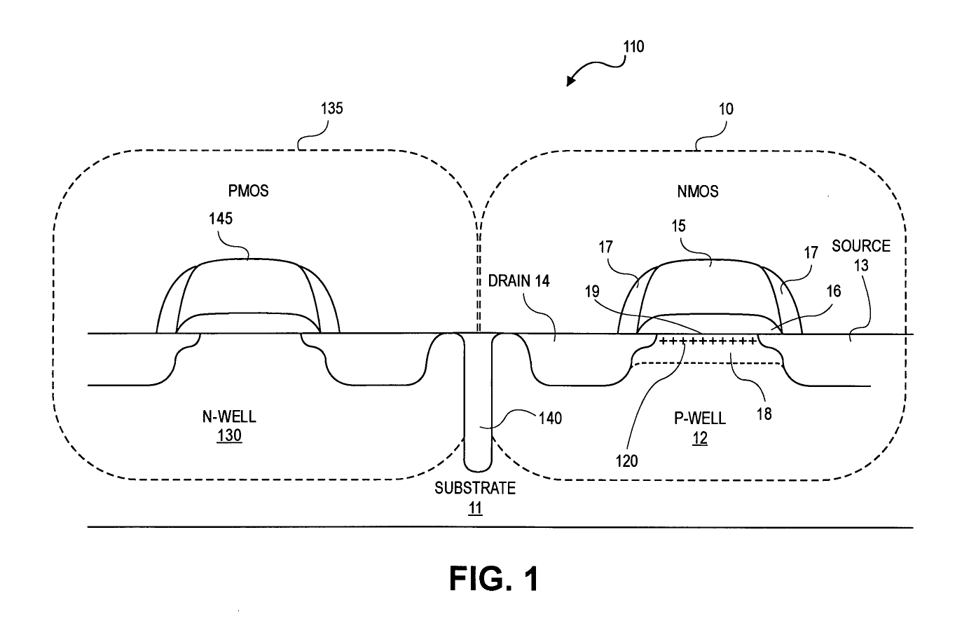

FIG. 1 shows a portion of a semiconductor structure 110 including an n-type metal-oxide semiconductor (NMOS) transistor 10 and a p-type metal-oxide semiconductor (PMOS) transistor 135. NMOS transistor 10 includes a p-type silicon (e.g., p-well 12) located on a substrate 11, an n-type source 13, an n-type drain 14, and a gate 15 located on top of a layer of gate dielectric 16. Gate 15 may be metal or polysilicon. Spacers 17 are formed on the sidewalls of gate 15. The same metal material may be used for gate 15 and a gate 145 of PMOS 135. Below gate 15 and gate dielectric 16 is a p-type channel 18 located between source 13 and drain 14. A carbon region 120 is formed at an interface 19 of channel 18 and gate dielectric 16.

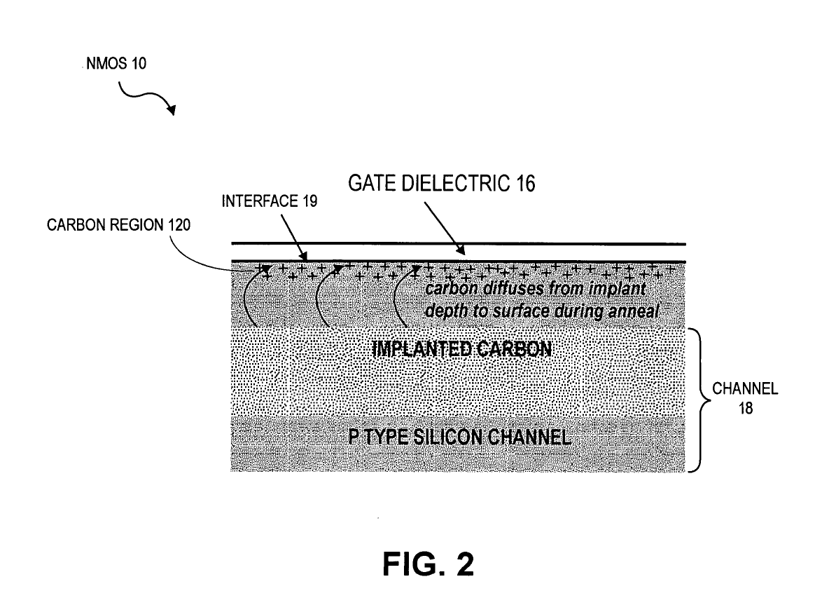

FIG. 2 shows the location of the implanted carbon and carbon region 120. In a process to be described in detail below, carbon may be implanted into channel 18. The implanted carbon diffuses from channel 18 to interface 19, causing an increase in fixed charge at the silicon surface. As the surface fixed charge increases, threshold voltage of NMOS 10 undergoes a negative shift. As NMOS has a positive threshold voltage, a negative shift in the threshold voltage results in a decreased threshold voltage for NMOS 10.

Implanting carbon into PMOS 135 may also cause a similar negative shift in the threshold voltage of the PMOS. However, a negative shift in the threshold voltage may not be desirable for PMOS in general, because PMOS has a negative threshold voltage. A negative shift to a negative threshold voltage results in an increase in the absolute value of the threshold voltage for the PMOS. Thus, prior to carbon implanting, PMOS 135 may be masked to prevent carbon from entering the PMOS.

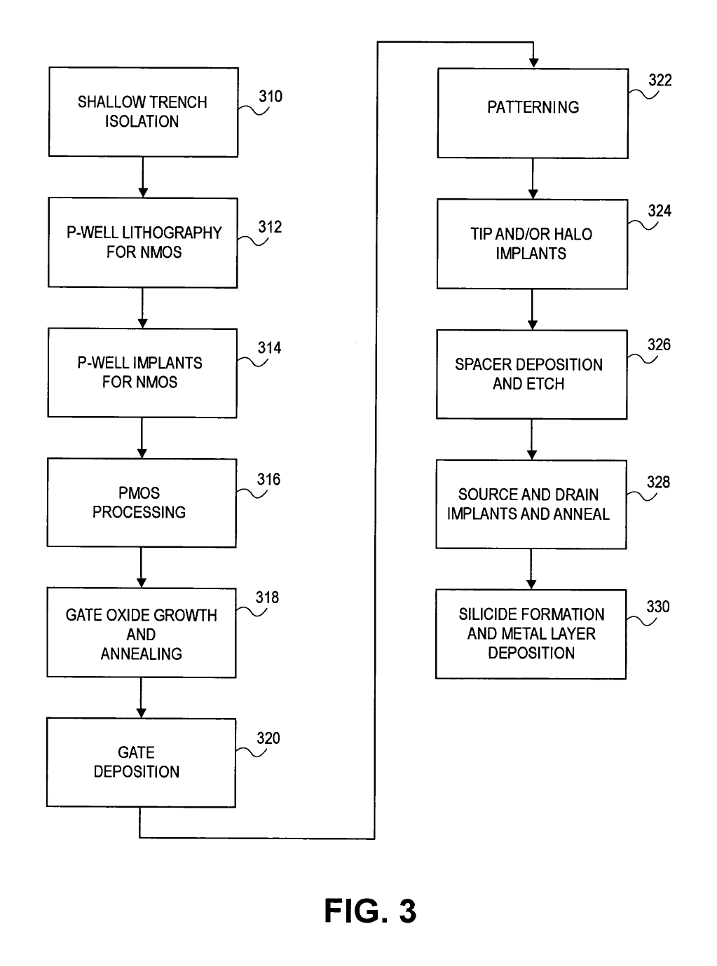

FIG. 3 shows a flowchart 30 for processing semiconductor structure 110 including NMOS 10 and PMOS 135 transistors. Referring also to FIG. 1, at block 310, a shallow trench 140 of about 0.3 microns deep (not drawn to scale) is etched and filled with oxide to isolate n-well 130 regions from p-well 12 regions. At block 312, p-well lithography is performed, in preparation for the implants to be made in p-well 12, to block PMOS 135 from p-well 12 implants. At block 314, an optional amorphization implant (e.g., 50 kev, 1e15 silicon atoms/cm²) may be made into the channel 18 area. As silicon is amorphized and then recrystallized, the silicon may incorporate much more carbon than the equilibrium solubility level. Thus, the amorphization implant may be used to increase the initial level of substitutional carbon. The optional amorphization implant is followed by a carbon implant (e.g., 5 keV, 2.4e15 carbon atoms/cm²) into the channel 18 area below yet-to-be formed gate dielectric layer 16 and gate 15.

During the p-well 12 optional amorphization and carbon implanting at block 314, a mask is placed on the portion of substrate 11 where PMOS 135 is to be formed. After the carbon implants, the mask is removed for subsequent PMOS processing at block 316 which may include n-well lithography and n-well implants. Alternatively, PMOS 135 may be processed before NMOS 10. In this scenario, a mask is placed on the processed PMOS 135 during NMOS processing and is removed after the NMOS processing.

At block 318, gate dielectric 16 is grown or deposited. Thereafter, an annealing process is performed during which much of the carbon implants diffuses from the channel 18 area to interface 19. Alternatively, the order in which gate dielectric 16 is deposited and the annealing process is performed may be interchanged. At block 320, gate 15 is deposited and a patterning process is performed at block 322 to create specific designs on the surface of semiconductor structure 110.

Following the patterning, at block 324, optional procedures of tip and/or halo implants may be performed at NMOS 10 and PMOS 135. Using NMOS 10 as an example, the tip implants refer to doping the shallow portion of source 13 and drain 14 that extend under gate 15. The halo implants refer to implants performed in channel 18 at an angle through gate 15. The halo implants are different from the p-well 12 implants at block 314 in which p-well 12 implants are directly made into the channel 18 area before gate 15 deposition. At block 326, spacers 17 may be deposited along the sidewalls of gate 15 and etched. Thereafter, at block 328, source 13 and drain 14 may be implanted and then annealed. The source/drain anneal may be followed by silicide formation and metal layers deposition at block 330. If a polysilicon gate is deposited at block 320, the polysilicon may be removed after the source/drain anneal at block 328 and replaced with a metal gate.

In an alternative embodiment, carbon may be implanted and diffused at block 330 instead of at block 314. In this scenario, carbon implanting and diffusion may occur after the polysilicon gate removal but before metal gate deposition.

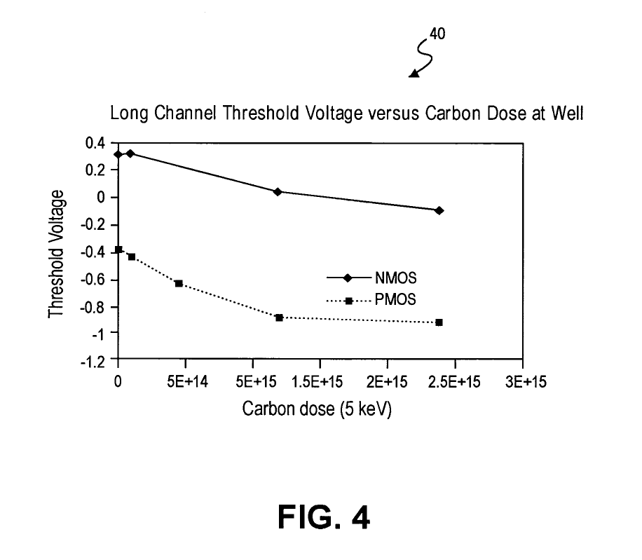

FIG. 4 shows an experimental chart 40 of long channel threshold voltage versus the amount of carbon dose in carbon region 120. Long channel threshold voltage refers to the voltage at which a long channel transistor forms an inversion layer (e.g., turns on). As the amount of carbon dose increases, threshold voltages become more negative. Chart 40 shows that the threshold voltage may shift more than 400 mV at a carbon dose of 2.4 E+15 and an energy level of 5 keV. The true threshold voltage shift may be more than the observed shifts in chart 40, because NMOS threshold voltages below zero and PMOS threshold voltages below −0.9V could not be accurately measured due to the limited voltage sweep in the measurement. Both NMOS and PMOS transistors show a similar shift in the negative direction, indicating an increase in fixed oxide charge instead of a change in dopant diffusion or deactivation.

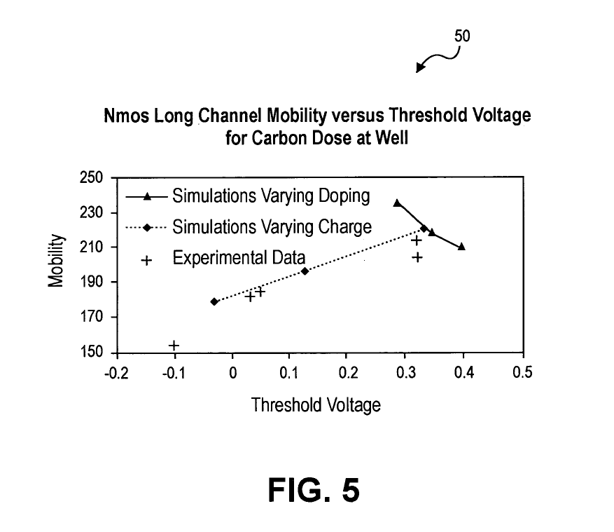

FIG. 5 shows a second experimental chart 50 of NMOS long channel mobility versus threshold voltage. Chart 50 also shows simulations of NMOS mobility versus long channel threshold voltage for changes in fixed charge and channel doping. When fixed charge increases, the mobility tends to decrease as threshold voltage decreases. However, when dopant concentration is reduced, the mobility tends to increase as the threshold voltage decreases. The experimental data in chart 50 clearly shows a reduction in mobility with reduced threshold voltage, consistent with increased fixed charge but inconsistent with reduced doping concentration. The simulations indicate that the mobility degradation is caused by increased electric field instead of increased scattering, and that mobility is recovered when the threshold voltage reduction from fixed charge is offset by a change in gate work function.

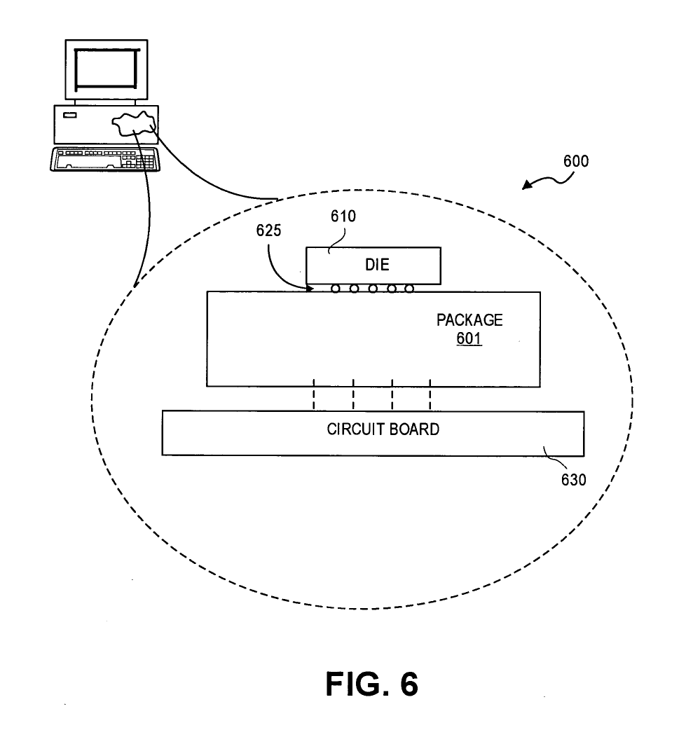

FIG. 6 shows a cross-sectional side view of an integrated circuit package that can be physically and electrically connected to a printed wiring board or printed circuit board (PCB) to form an electronic assembly. The electronic assembly can be part of an electronic system such as a computer (e.g., desktop, laptop, hand-held, server, etc.), wireless communication device (e.g., cellular phone, cordless phone, pager, etc.), computer-related peripheral (e.g., printers, scanners, monitors, etc.), entertainment device (e.g., television, radio, stereo, tape and compact disc player, videocassette recorder, MP3 (Motion Picture Experts Group, Audio Layer 3) player, etc.), and the like. FIG. 6 illustrates the package as part of a desktop computer.

FIG. 6 shows electronic assembly 600 including die 610 physically and electrically connected to package substrate 601. Die 610 is an integrated circuit die, such as a processor die. In one embodiment, die 610 includes semiconductor structure 110 of FIG. 1. Electrical contact points (e.g., contact pads on a surface of die 610) are connected to package substrate 601 through conductive bump layer 625. Package substrate 601 may be used to connect electronic assembly 600 to printed circuit board 630, such as a motherboard or other circuit board.

In the foregoing specification, specific embodiments have been described. It will, however, be evident that various modifications and changes can be made thereto without departing from the broader spirit and scope of the appended claims. The specification and drawings are, accordingly, to be regarded in an illustrative rather than a restrictive sense.

What is claimed is:

1. A method comprising:
implanting carbon into a p-type silicon channel of an n-type metal-oxide semiconductor (NMOS) transistor of a substrate.

2. The method of claim 1 further comprising:
annealing the implanted carbon to diffuse the carbon to an interface of the silicon channel and a gate dielectric layer of the NMOS transistor.

3. The method of claim 1 further comprising:
controlling a threshold voltage of the NMOS transistor by adjusting an amount of carbon dose implanted.

4. The method of claim 1 wherein implanting the carbon is performed at an energy level of substantially 5 keV.

5. The method of claim 1 wherein implanting the carbon is performed with a carbon dose of substantially 2.4e15 atoms/cm².

6. The method of claim 1 further comprising:
forming a metal gate after implanting the carbon.

7. The method of claim 1 further comprising:
masking a p-type metal-oxide semiconductor (PMOS) transistor of the substrate before implanting the carbon.

8. The method of claim 1 further comprising:
performing an amorphization implant in the silicon channel before implanting the carbon.

9. The method of claim 8 wherein the amorphization implant is performed with energy of substantially 50 keV and a silicon dose of substantially 1e15 atoms/cm².

10. An apparatus comprising:
a gate dielectric layer;
a p-type silicon channel of an n-type metal-oxide semiconductor (NMOS) transistor; and
a carbon region near an interface of the gate dielectric layer and the silicon channel.

11. The apparatus of claim 10 further comprises:
a metal gate on top of the gate dielectric layer.

12. The apparatus of claim 10 wherein the carbon region includes a pre-determined amount of carbon to control a threshold voltage of the NMOS transistor.

13. The apparatus of claim 10 wherein the carbon region is formed by implanting the carbon into the silicon channel at an energy level of substantially 5 keV.

14. The apparatus of claim 10 wherein the carbon region is formed by implanting a carbon dose of substantially 2.4e15 atoms/cm² into the silicon channel.

15. A system comprising:
a computing device comprising a microprocessor comprising a plurality of circuit devices on a substrate, each of the plurality of circuit devices comprising:
an n-type metal-oxide semiconductor (NMOS) transistor on a substrate;
a p-type metal-oxide semiconductor (PMOS) transistor on the substrate; and
a carbon region near an interface of a gate dielectric layer and a p-type silicon channel of the NMOS transistor.

16. The system of claim 15 wherein the carbon region includes a pre-determined amount of carbon to control a threshold voltage of the NMOS transistor.

17. The system of claim 15 further comprises:
a first gate on the NMOS transistor; and
a second gate on the PMOS transistor, wherein the first gate and the second gate are made of the same metal material.

18. The system of claim 15 wherein the carbon region is formed by implanting the carbon into the silicon channel with energy of substantially 5 keV.

19. The system of claim 15 wherein the carbon region is formed by implanting a carbon dose of substantially 2.4e15 atoms/cm² into the silicon channel.
